(19) United States
(12) Patent Application Publication
(10) Pub. No.: US 2026/0358729 A1
(43) Pub. Date: Nov. 12, 2026

(54) OPTICAL SYSTEM, LITHOGRAPHY UNIT, AND METHOD FOR OPERATING AN OPTICAL SYSTEM OF A LITHOGRAPHY UNIT

(71) Applicant: Carl Zeiss SMT GmbH, Oberkochen (DE)

(72) Inventors: Matthias FETZER, Stuttgart (DE); Luca METTENLEITER, Neresheim (DE); Carina KURTH, Stuttgart (DE)

(21) Appl. No.: 19/213,518

(22) Filed: May 20, 2025

Related U.S. Application Data
(63) Continuation of application No. PCT/EP2023/082517, filed on Nov. 21, 2023.

(30) Foreign Application Priority Data
Nov. 22, 2022 (DE) 10 2022 212 463.4

(51) Int. Cl. G03F 7/00

(52) U.S. Cl. CPC G03F 7/7085; G03F 7/70266; G03F 7/70591; G03F 7/709

(57) ABSTRACT

An optical system for a lithography apparatus, comprising: an optical element; a plurality of actuators coupled to the optical element to serve to set a position of the optical element in a first number of rigid body degrees of freedom; a sensor frame comprising a second number of sensor elements for acquiring sensor data from the optical element, wherein the second number is greater than the first number; and an ascertainment device serving to use the acquired sensor data to ascertain a deformation-corrected actual position of the optical element relative to the sensor frame in the first number of rigid body degrees of freedom, wherein a deformation of the sensor frame is corrected in the deformation-corrected actual position.

### CROSS-REFERENCE TO RELATED APPLICATIONS

The present application is a continuation of, and claims benefit under 35 USC 120 to, international application No. PCT/EP 2023/082517, filed Nov. 21, 2023, which claims benefit under 35 USC 119 of German Application No. 10 2022 212 463.4, filed Nov. 22, 2022. The entire disclosure of each of these applications is incorporated by reference herein.

### FIELD

The present disclosure relates to an optical system, to a lithography apparatus having such an optical system and to a method for operating such an optical system.

### BACKGROUND

Microlithography is used for producing microstructured components, such as for example integrated circuits. The microlithography process is performed using a lithography apparatus, which comprises an illumination system and a projection system. The image of a mask (reticle) illuminated via the illumination system is projected via the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV lithography apparatuses which use light at a wavelength in the range of 0.1 nanometer (nm) to 30 nm, for example 13.5 nm, are currently being developed. Since most materials absorb light at this wavelength, such EUV lithography apparatuses typically use reflective optics units, i.e. mirrors, instead of refractive optics units, i.e. lens elements, as used previously.

The demands on the accuracy and precision of the imaging properties of lithography apparatuses are constantly increasing. From a dynamic point of view, it is desirable to minimize the influence of disturbance inputs on the movement of various component parts of the lithography apparatus in this context. For example, very precise positioning of optical components, especially mirrors, of the lithography apparatus is generally desired. Quasi-static or dynamic disturbances of optical components may be created, for example, by the movement of other component parts of the lithography apparatus.

It is generally desirable to largely mechanically decouple optical components of the lithography apparatus, for example mirrors, from other component parts and to suppress or compensate the disturbances transmitted despite this decoupled state.

### SUMMARY

The present disclosure seeks to provide an improved optical system for a lithography apparatus and an improved method for operating an optical system in a lithography apparatus.

According to a first aspect, an optical system for a lithography apparatus is proposed. The optical system comprises: an optical element; a plurality of actuators that are coupled to the optical element and serve to set a position of the optical element in a first number of rigid body degrees of freedom; a sensor frame having a second number of sensor elements for acquiring sensor data from the optical element, wherein the second number is greater than the first number; and an ascertainment device serving to use the acquired sensor data to ascertain a deformation-corrected actual position of the optical element relative to the sensor frame in the first number of rigid body degrees of freedom, wherein a deformation of the sensor frame is corrected in the deformation-corrected actual position.

The sensor elements for measuring the position of the optical element can be arranged on, e.g. attached to, the sensor frame. In relation to its rigid body degrees of freedom, the position of the optical element relative to the sensor frame can be ascertained with the aid of the sensor data from the optical element acquired by the sensor elements. Without a correction, a deformation of the sensor frame would typically lead to an error in the ascertained actual position of the optical element on account of a mechanical disturbance of the sensor frame. That is to say, without a correction of the deformation of the sensor frame there would typically be faulty control of the position of the optical element and hence imaging errors of the optical system.

As a result of the present case providing more sensor elements for detecting the position of the optical element than are needed for an ascertainment of the rigid body degrees of freedom of the optical element—also referred to as “over-sensing”—a deformation of the sensor frame may also be detected in addition to the determination of the rigid body position of the optical element. Hence, it is possible to take account of a deformation of the sensor frame, which otherwise remains undetected, when controlling the position of the optical element. Consequently, it is possible to achieve an accurate positional measurement of the optical element relative to the sensor frame as a reference despite a deformation of the sensor frame. As a result, it is possible to compensate for mechanical disturbances of the sensor frame. For example, feedback control of the position of the optical element can be improved in the presence of deformations of the sensor frame since the control does not follow the deformation of the sensor frame. It is therefore possible to reduce or avoid imaging errors of the optical system.

Moreover, the proposed optical system can also be used to detect the deformation of the sensor frame or the deformation-corrected actual position of the optical element based thereon, during an exposure of the optical element, e.g. during an exposure of the lithography apparatus.

In the present description, the deformation-corrected actual position of the optical element denotes an actual position of the optical element that has been corrected in relation to a deformation of the sensor frame. A further actual position of the optical element that takes account of a deformation of the optical element itself may also be detected—instead of a deformation-corrected actual position of the optical element in which a deformation of the sensor frame is corrected—in embodiments.

For example, the first number of rigid body degrees of freedom of the optical element is at least three and/or six. For example, the second number of sensor elements is a sum of the first number of sensor elements and a number of additional sensor elements, wherein the number of additional sensor elements is 1, 2, 3 and/or a number greater than 3.

For example, the optical element has six rigid body degrees of freedom, or the position of the optical element is settable in six rigid body degrees of freedom via the actuators (i.e. the first number is six). In general, the six rigid body degrees of freedom comprise three translational degrees of freedom (translation in three spatial directions X, Y, Z; the three spatial directions X, Y, Z span a three-dimensional space for example) and three rotational degrees of freedom (rotation about three axes that correspond to the three spatial directions X, Y, Z). Furthermore, the sensor frame for example comprises seven or more sensor elements for acquiring the sensor data from the optical element. It is well known that the determination of the rigid body position of a body, e.g. the optical element, in six degrees of freedom generally involves six mutually independent position measurements (e.g. at different locations on the body), i.e. for example six mutually independent sensor elements. As a result of seven or more sensor elements being provided in the present case, i.e. an additional sensor element in the case of seven sensor elements and more than one additional sensor element in the case of more than seven sensor elements, it is possible to use the one or more additional sensor elements to detect a deviation of the sensor frame from a rigid body, i.e. to detect a deformation of the sensor frame.

The optical element of the lithography apparatus is for example a mirror of the lithography apparatus, e.g. a mirror of a projection optics unit of the lithography apparatus. However, the optical element may also be any other optical element in the lithography apparatus.

For example, the optical system comprises a force frame. The force frame is for example mounted in vibration-decoupled fashion with respect to a floor. For example, with the aid of the plurality of actuators, the optical element is fastened so as to be movable on the force frame, in order to be able to set the position of the optical element. The plurality of actuators for example represent an actuator system of a control loop for controlling the position of the optical element.

For example, the sensor frame is mounted in vibration-decoupled fashion with respect to the force frame. For example, the sensor frame serves as an (e.g. optical) reference for the position measurement.

The sensor elements are configured to acquire sensor data for the purpose of ascertaining a position of the optical element relative to the sensor frame. For example, the sensor elements comprise interferometers and/or other measuring apparatuses for detecting a position of the optical element. For example, the sensor elements are configured for one-dimensional measurement and/or distance measurement. For example, each sensor element is configured to detect a distance between the sensor frame (such as the location at which the corresponding sensor element is attached to the sensor frame) and the optical element (such as a target location on the optical element assigned to the respective sensor element). For example, the optical element may comprise a plurality of target elements (targets) that appropriately interact with the plurality of sensor elements on the sensor frame during the position measurement. For example, the target elements are arranged (e.g. visibly arranged) on the optical element. For example, a number of target elements corresponds to the number of sensor elements, i.e. the second number. For example, light (e.g. laser light) transmitted by a respective sensor element radiates in the direction of a corresponding target element or onto the corresponding target element. For example, the target elements may be reflector elements for reflecting light emitted by the sensor elements.

For example, the optical system comprises a control apparatus. For example, the ascertainment device is a part of the control apparatus. The ascertainment device can ascertain the deformation-corrected actual position of the optical element on the basis of the acquired sensor data. As a result of “over-sensing” (the second number of sensor elements greater than the first number of rigid body degrees of freedom), the captured sensor data contain more information than needed to ascertain a rigid body position of the optical element. Hence, a deviation of the sensor frame from a rigid body (deformation of the sensor frame) can be recognized on the basis of the sensor data. Furthermore, the sensor data may be used to ascertain a deformation-corrected actual position of the optical element relative to the sensor frame in the first number of rigid body degrees of freedom.

For example, the ascertainment device is configured to use the acquired sensor data to initially ascertain a deformation of the sensor frame. For example, the ascertainment device is furthermore configured to use the sensor data and the ascertained deformation of the sensor frame to ascertain the deformation-corrected actual position of the optical element. In examples, the ascertainment device may also be configured to use the acquired sensor data to directly ascertain the deformation-corrected actual position of the optical element, i.e. ascertain this without calculating the deformation of the sensor frame individually. For example, the deformation-corrected actual position of the optical element is determined directly by way of a simulation calculation.

For example, the lithography apparatus is an EUV or a DUV lithography apparatus. EUV stands for “extreme ultraviolet” and refers to a wavelength of the operating light in the range from 0.1 nm to 30 nm, for example 13.5 nm. DUV stands for “deep ultraviolet” and refers to a wavelength of the operating light between 30 nm and 250 nm.

The EUV or DUV lithography apparatus comprises an illumination system and a projection system. For example, using the EUV or DUV lithography apparatus, the image of a mask (reticle) illuminated via the illumination system is projected via the projection system onto a substrate, for example a silicon wafer, which is coated with a light-sensitive layer (photoresist) and arranged in the image plane of the projection system, in order to transfer the mask structure to the light-sensitive coating of the substrate.

For example, the optical system is a projection optics unit or part of a projection optics unit of the lithography apparatus. However, the optical system may also be an illumination system.

According to an embodiment of the first aspect, the ascertainment device is configured to use the sensor data to correct a quasi-static deformation of the sensor frame.

Quasi-static deformations usually play a significant role in the case of a sensor frame in a lithography apparatus, especially in an EUV lithography apparatus. Consequently, taking account of and correcting quasi-static deformations of the sensor frame can allow a positional accuracy of the optical element to be significantly increased during the position measurement of the optical element.

According to an embodiment of the first aspect, the ascertainment device is configured to use the sensor data to correct a dynamic deformation of the sensor frame.

For example, a dynamic deformation of the sensor frame comprises a vibration of the sensor frame in one or more of its eigenmodes. For example, a dynamic deformation of the sensor frame comprises a vibration of the sensor frame in its first eigenmode and/or in further eigenmodes. For example, a vibration of the sensor frame in a respective eigenmode includes a vibration at a corresponding eigenfrequency of the sensor frame.

According to an embodiment of the first aspect, at least one of the sensor elements is arranged in a region of a deflection of the sensor frame in relation to a quasi-static and/or a dynamic disturbance.

As a result of arranging at least one sensor element in a region of a deflection of the sensor frame in relation to a quasi-static and/or a dynamic disturbance, it is possible to detect a deformation of the sensor frame on account of the corresponding disturbance particularly well.

The at least one sensor element which is arranged in the region of the deflection can be one of the additional sensor elements that is not required for ascertaining the rigid body position.

For example, the region of a deflection is a region of a maximum deflection of the sensor frame in relation to a quasi-static and/or a dynamic disturbance.

In the case of a dynamic disturbance (i.e. a vibrational excitation of the sensor frame), the region of a deflection is for example a region of a vibration amplitude that differs from zero, e.g. a maximum vibration amplitude, of the sensor frame in relation to an eigenmode of the sensor frame. In the case of a dynamic vibrational excitation of the sensor frame, a region of maximum vibration amplitude is an antinodal region of an eigenmode of the sensor frame for example.

According to an embodiment of the first aspect, a number of sensor elements, the number corresponding to the first number, are each arranged in a non-deflection region of the sensor frame in relation to a quasi-static and/or a dynamic disturbance.

For example, the sensor elements comprise a first group of sensor elements, the number of which corresponds to the first number and which are configured to detect the optical element as a rigid body. In this embodiment, the sensor elements of the first group are for example arranged in the non-deflection region of the sensor frame in order to better detect the optical element as a rigid body. Furthermore, the sensor elements can comprise a second group of sensor elements, the number of which is at least one and which are configured to detect a deformation of the sensor frame.

For example, a non-deflection region of the sensor frame is a region of the sensor frame which does not move and/or hardly moves in the event of a deformation caused by a mechanical disturbance.

In the event of a dynamic vibrational excitation of the sensor frame, a non-deflection region of the sensor frame is for example a region of minimal vibration amplitude and/or a nodal region of an eigenmode of the sensor frame.

According to an embodiment of the first aspect, the optical system furthermore comprises a vibration sensor device for detecting one or more excitation frequencies of a vibrational excitation of the optical system. Furthermore, the ascertainment device is configured to ascertain the deformation-corrected actual position of the optical element, in the case of which a deformation of the sensor frame is corrected, when the one or more detected excitation frequencies are less than or equal to a predetermined threshold value.

Usually, the optical element is more rigid than the sensor frame at relatively small excitation frequencies. Hence vibrational excitations of the optical element are usually small at excitation frequencies that are less than or equal to the predetermined threshold value. Consequently, the optical element may be assumed to be (e.g. approximately) a rigid body at these excitation frequencies. As a result of assuming the optical element to be a rigid body (i.e. assuming that a deformation of the optical element is small and/or not present), the sensor data can be used to detect a deformation of the sensor frame or better ascertain a deformation-corrected actual position of the optical element, in which the deformation of the sensor frame is corrected.

For example, the vibrational excitation of the optical system is a vibrational excitation caused by movable components within the optical system. For example, the vibrational excitation of the optical system is a vibrational excitation of the optical element.

For example, the vibration sensor device comprises one or more vibration sensors. For example, a corresponding vibration sensor comprises one or more piezo elements or other types of vibration detectors. For example, the vibration sensor device comprises a control unit for ascertaining the excitation frequency (frequencies) of the detected vibration. For example, the excitation frequency (frequencies) comprises (comprise) one or more individual frequency values and/or one or more frequency ranges.

For example, the vibration sensor device is configured to detect a dynamic vibrational excitation of the optical system, of the optical element and/or of the sensor frame.

According to an embodiment of the first aspect, the ascertainment device is configured to use the sensor data to ascertain a further actual position of the optical element in the first number of rigid body degrees of freedom when the one or more detected excitation frequencies are greater than the predetermined threshold value, wherein a deformation of the optical element is corrected at the further actual position.

Hence a deformation of the optical element may be corrected when ascertaining the actual position in the event of high excitation frequencies (greater than the threshold value), at which the optical element can no longer be assumed to be a rigid body. This is possible since the sensor frame may be considered to be at least approximately rigid at high excitation frequencies (greater than the threshold value), and hence it is not necessary to correct for the deformation of the sensor frame.

According to embodiments of the first aspect, the predetermined threshold value is 1 kiloHertz (kHz), 750 Hz, 500 Hz, 300 Hz, 200 Hz, 100 Hz, 50 Hz, 20 Hz or 10 Hz.

According to an embodiment of the first aspect, the optical system furthermore comprises a closed-loop control device for controlling the position of the optical element on the basis of a deviation of the ascertained deformation-corrected actual position, in which a deformation of the sensor frame is corrected, from a target position or on the basis of a deviation of the ascertained further actual position, in which a deformation of the optical element is corrected, from a target position.

Since the control (feedback control) of the position of the optical element in the first alternative of this embodiment is based on the ascertained deformation-corrected actual position of the optical element, in which a deformation of the sensor frame is corrected, this can avoid the controlled variable following a deformation of the sensor frame.

Since the control of the position of the optical element in the second alternative of this embodiment is based on the ascertained further actual position of the optical element, in which a deformation of the optical element is corrected, this can avoid the control being performed on the basis of an incorrectly ascertained actual position.

For example, the closed-loop control device is part of the control apparatus of the optical system.

According to an embodiment of the first aspect, the optical element is a first optical element. Moreover, the optical system furthermore comprises at least one further optical element and a plurality of actuators that are coupled to the at least one further optical element and serve to set a position of the at least one further optical element in a third number of rigid body degrees of freedom. For each of the at least one further optical element, the sensor frame furthermore comprises a number of sensor elements, the number corresponding to the third number, for acquiring sensor data from the at least one further optical element. Moreover, the ascertainment device is configured to use the sensor data from the first optical element to ascertain a deformation of the sensor frame and to use the acquired sensor data from the at least one further optical element to ascertain a deformation-corrected actual position of the at least one further optical element relative to the sensor frame in the third number of rigid body degrees of freedom on the basis of the deformation of the sensor frame ascertained for the first optical element.

Hence the deformation of the sensor frame that was ascertained on the basis of the acquired sensor data from the optical element (i.e. the first optical element) may also be used to ascertain the deformation-corrected actual position of the at least one further optical element. Hence, a number of sensor elements (second number) that is greater than the corresponding number of rigid body degrees of freedom (first number) (“over-sensing”) is only needed for the first optical element but not for the further optical elements.

According to a further aspect, further sensor elements are provided for detecting a deformation of the sensor frame, wherein the further sensor elements are arranged on, e.g. attached to, a wafer holder of the lithography apparatus.

For example, a further optical system for a lithography apparatus is proposed according to the further aspect. The further optical system comprises: an optical element; a plurality of actuators that are coupled to the optical element and serve to set a position of the optical element in a first number of rigid body degrees of freedom; a sensor frame having a second number of sensor elements for acquiring sensor data from the optical element, wherein the second number is greater than or equal to the first number; a wafer holder having a third number of further sensor elements for acquiring further sensor data from the sensor frame, wherein the third number is greater than the first number; and a further ascertainment device for using the acquired further sensor data to ascertain a deformation of the sensor frame and for using the acquired sensor data to ascertain a deformation-corrected actual position of the optical element relative to the sensor frame in the first number of rigid body degrees of freedom, wherein the ascertained deformation of the sensor frame is corrected in the deformation-corrected actual position.

According to a second aspect, a lithography apparatus having an optical system as described above is proposed.

According to a third aspect, a method for operating an optical system of a lithography apparatus is proposed. The optical system comprises an optical element and a plurality of actuators that are coupled to the optical element and serve to set a position of the optical element in a first number of rigid body degrees of freedom. The method includes the steps of: a) acquiring sensor data from the optical element with the aid of a second number of sensor elements on a sensor frame, wherein the second number is greater than the first number; and b) using the acquired sensor data to ascertain a deformation-corrected actual position of the optical element relative to the sensor frame in the first number of rigid body degrees of freedom, wherein a deformation of the sensor frame is corrected in the deformation-corrected actual position.

According to an embodiment of the third aspect, the method comprises a step of acquiring one or more excitation frequencies of a vibrational excitation of the optical system. Moreover, step b) is carried out should the one or more detected excitation frequencies be less than or equal to a predetermined threshold value.

According to an embodiment of the third aspect, should the one or more detected excitation frequencies be greater than the predetermined threshold value, a further actual position of the optical element, in which a deformation of the optical element is corrected, is ascertained in the first number of rigid body degrees of freedom on the basis of the sensor data.

According to an embodiment of the third aspect, the method comprises a step of controlling the position of the optical element on the basis of a deviation of the ascertained deformation-corrected actual position, in which a deformation of the sensor frame is corrected, from a target position or on the basis of a deviation of the ascertained further actual position, in which a deformation of the optical element is corrected, from a target position.

“A” or “an” in the present case should not necessarily be understood as a restriction to exactly one element. Rather, there may also be multiple elements, for example two, three or more. Any other numeral used here should also not be understood as a restriction to exactly the stated number of elements. Rather, numerical deviations upward and downward are possible, unless indicated otherwise.

The embodiments and features described for the optical system apply correspondingly to the proposed method, and vice versa.

Further possible implementations of the disclosure also comprise non-explicitly mentioned combinations of features or embodiments described hereinabove or hereinafter with regard to the exemplary embodiments. A person skilled in the art will also add individual aspects as improvements or supplementations to the respective basic form of the disclosure.

Further embodiments and aspects of the disclosure are the subject matter of the dependent claims and of the exemplary embodiments of the disclosure described below. The disclosure is explained in greater detail hereinafter on the basis of embodiments with reference to the accompanying figures.

### BRIEF DESCRIPTION OF THE DRAWINGS

FIG. 1 shows a schematic meridional section of a projection exposure apparatus for EUV projection lithography, according to one embodiment;

FIG. 2 shows an optical system of the projection exposure apparatus from FIG. 1 according to one embodiment;

FIG. 3 shows an enlarged detail from FIG. 2;

FIG. 4 elucidates a vibrational excitation of a sensor frame of the optical system from FIG. 2 according to one embodiment;

FIG. 5 shows functional components of a control apparatus of the optical system from FIG. 2 according to one embodiment; and

FIG. 6 shows a flowchart of a method for operating an optical system of a projection exposure apparatus, according to one embodiment.

### DETAILED DESCRIPTION

In the figures, identical or functionally identical elements have been provided with the same reference signs, unless indicated otherwise. It should also be noted that the representations in the figures are not necessarily to scale.

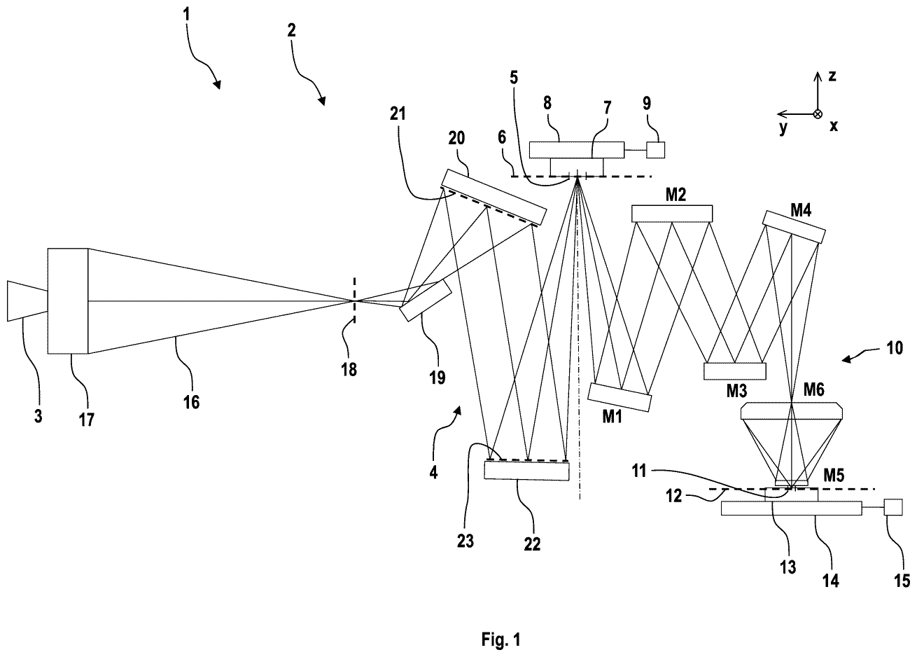

FIG. 1 shows an embodiment of a projection exposure apparatus 1 (lithography apparatus), for example an EUV lithography apparatus. In addition to a light source or radiation source 3, an embodiment of an illumination system 2 of the projection exposure apparatus 1 has an illumination optics unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 shows, for explanation purposes, a Cartesian coordinate system with an x-direction x, a y-direction y, and a z-direction z. The x-direction x runs perpendicularly into the plane of the drawing. The y-direction y runs horizontally, and the z-direction z runs vertically. The scanning direction runs in the y-direction y in FIG. 1. The z-direction z runs perpendicularly to the object plane 6.

The projection exposure apparatus 1 comprises a projection optics unit 10. The projection optics unit 10 serves for imaging the object field 5 into an image field 11 in an image plane 12. The image plane 12 extends parallel to the object plane 6. In an alternative, an angle that differs from 0° is also possible between the object plane 6 and the image plane 12.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction y. The displacement firstly of the reticle 7 by way of the reticle displacement drive 9 and secondly of the wafer 13 by way of the wafer displacement drive 15 can be implemented so as to be mutually synchronized.

The light source 3 is an EUV radiation source. The light source 3 emits for example EUV radiation 16, which is also referred to below as used radiation, illumination radiation or illumination light. The used radiation 16 has for example a wavelength in the range of between 5 nm and 30 nm. The light source 3 may be a plasma source, for example an LPP (laser produced plasma) source or a GDPP (gas discharge produced plasma) source. It may also be a synchrotron-based radiation source. The light source 3 may be a free electron laser (FEL).

The illumination radiation 16 emanating from the light source 3 is focused by a collector 17. The collector 17 may be a collector with one or more ellipsoidal and/or hyperboloidal reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated, both to optimize its reflectivity for the used radiation and to suppress extraneous light.

Downstream of the collector 17, the illumination radiation 16 propagates through an intermediate focus in an intermediate focal plane 18. The intermediate focal plane 18 can represent a separation between a radiation source module, comprising the light source 3 and the collector 17, and the illumination optics unit 4.

The illumination optics unit 4 comprises a deflection mirror 19 and, disposed downstream thereof in the beam path, a first facet mirror 20. The deflection mirror 19 may be a plane deflection mirror or, in an alternative to that, a mirror with a beam-influencing effect going beyond the pure deflection effect. In an alternative to that or in addition, the deflection mirror 19 may be in the form of a spectral filter that separates a used light wavelength of the illumination radiation 16 from extraneous light at a different wavelength. Should the first facet mirror 20 be arranged in a plane of the illumination optics unit 4 which is optically conjugate to the object plane 6 as a field plane, this facet mirror is also referred to as a field facet mirror. The first facet mirror 20 comprises a multiplicity of individual first facets 21, which can also be referred to as field facets. Only some of these first facets 21 are illustrated in FIG. 1 by way of example.

The first facets 21 may take the form of macroscopic facets, for example rectangular facets or facets with an arc-shaped or part-circular edge contour. The first facets 21 may take the form of plane facets or, in an alternative to that, convexly or concavely curved facets.

As is known for example from DE 10 2008 009 600 A1, the first facets 21 themselves may each also be composed of a multiplicity of individual mirrors, for example a multiplicity of micromirrors. The first facet mirror 20 can be designed for example as a microelectromechanical system (MEMS system). For details, reference is made to DE 10 2008 009 600 A1.

The illumination radiation 16 propagates horizontally, i.e. in the y-direction y, between the collector 17 and the deflection mirror 19.

In the beam path of the illumination optics unit 4, a second facet mirror 22 is disposed downstream of the first facet mirror 20. Should the second facet mirror 22 be arranged in a pupil plane of the illumination optics unit 4, it is also referred to as a pupil facet mirror. The second facet mirror 22 may also be spaced apart from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or alternatively may be facets composed of micromirrors. For details, reference is likewise made to DE 10 2008 009 600 A1.

The second facets 23 may have plane reflection surfaces or, in an alternative to that, convexly or concavely curved reflection surfaces.

The illumination optics unit 4 thus forms a doubly faceted system. This fundamental principle is also referred to as a fly's eye integrator.

It might be desirable to arrange the second facet mirror 22 not exactly in a plane that is optically conjugate to a pupil plane of the projection optics unit 10. For example, the second facet mirror 22 may be arranged so as to be tilted in relation to a pupil plane of the projection optics unit 10, as described for example in DE 10 2017 220 586 A1.

The second facet mirror 22 is used to image the individual first facets 21 into the object field 5. The second facet mirror 22 is the last beam-shaping mirror or actually the last mirror for the illumination radiation 16 in the beam path upstream of the object field 5.

In a further embodiment (not illustrated) of the illumination optics unit 4, a transfer optics unit contributing for example to the imaging of the first facets 21 into the object field 5 may be arranged in the beam path between the second facet mirror 22 and the object field 5. The transfer optics unit may have exactly one mirror or, in an alternative to that, two or more mirrors, which are arranged one behind another in the beam path of the illumination optics unit 4. The transfer optics unit may for example comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the first facet mirror 20 and the second facet mirror 22.

In a further embodiment of the illumination optics unit 4, the deflection mirror 19 may also be omitted, and so the illumination optics unit 4 may then have exactly two mirrors downstream of the collector 17, specifically the first facet mirror 20 and the second facet mirror 22.

The imaging of the first facets 21 into the object plane 6 via the second facets 23 or using the second facets 23 and a transfer optics unit is, as a rule, only approximate imaging.

The projection optics unit 10 comprises a plurality of mirrors Mi, which are consecutively numbered in accordance with their arrangement in the beam path of the projection exposure apparatus 1.

In the example illustrated in FIG. 1, the projection optics unit 10 comprises six mirrors M1 to M6. Alternatives with four, eight, ten, twelve or any other number of mirrors Mi are likewise possible. The projection optics unit 10 is a doubly obscured optics unit. The penultimate mirror M5 and the last mirror M6 each have a passage opening for the illumination radiation 16. The projection optics unit 10 has an image-side numerical aperture which is greater than 0.5 and which may also be greater than 0.6 and which, for example, may be 0.7 or 0.75.

Reflection surfaces of the mirrors Mi may take the form of free-form surfaces without an axis of rotational symmetry. In an alternative to that, the reflection surfaces of the mirrors Mi may take the form of aspherical surfaces with exactly one axis of rotational symmetry of the reflection surface shape. Just like the mirrors of the illumination optics unit 4, the mirrors Mi may have highly reflective coatings for the illumination radiation 16. These coatings may be designed as multilayer coatings, for example with alternating layers of molybdenum and silicon.

The projection optics unit 10 has a large object-image offset in the y-direction y between a y-coordinate of a center of the object field 5 and a y-coordinate of the center of the image field 11. This object-image offset in the y-direction y can be of approximately the same magnitude as a z-distance between the object plane 6 and the image plane 12.

For example, the projection optics unit 10 may have an anamorphic design. It has for example different imaging scales βx, βy in the x- and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optics unit 10 consequently leads to a reduction in size with a ratio of 4:1 in the x-direction x, i.e. in a direction perpendicular to the scanning direction.

The projection optics unit 10 leads to a reduction in size of 8:1 in the y-direction y, i.e. in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 can be the same or can differ, depending on the embodiment of the projection optics unit 10. Examples of projection optics units with different numbers of such intermediate images in the x-direction x and y-direction y are known from US 2018/0074303 A1.

In each case, one of the second facets 23 is assigned to exactly one of the first facets 21 for forming in each case an illumination channel for illuminating the object field 5. This may yield for example illumination according to the Köhler principle. The far field is decomposed into a multiplicity of object fields 5 with the aid of the first facets 21. The first facets 21 create a plurality of images of the intermediate focus on the second facets 23 respectively assigned to them.

The first facets 21 are each imaged onto the reticle 7 by an assigned second facet 23 and overlaid over one another for the purpose of illuminating the object field 5. The illumination of the object field 5 is for example as homogeneous as possible. It can have a uniformity error of less than 2%. Field uniformity may be achieved by overlaying different illumination channels.

The illumination of the entrance pupil of the projection optics unit 10 can be defined geometrically by an arrangement of the second facets 23. The intensity distribution in the entrance pupil of the projection optics unit 10 can be set by selecting the illumination channels, for example the subset of the second facets 23, which guide light. This intensity distribution is also referred to as illumination setting or illumination pupil filling.

A likewise preferred pupil uniformity in the region of portions of an illumination pupil of the illumination optics unit 4 which are illuminated in a defined manner may be achieved by a redistribution of the illumination channels.

Further aspects and details of the illumination of the object field 5 and for example of the entrance pupil of the projection optics unit 10 are described below.

The projection optics unit 10 may have for example a homocentric entrance pupil. The latter may be accessible. It may also be inaccessible.

The entrance pupil of the projection optics unit 10 regularly cannot be exactly illuminated with the second facet mirror 22. In the case of an imaging process of the projection optics unit 10 that images the center of the second facet mirror 22 telecentrically onto the wafer 13, the aperture rays often do not intersect at a single point. However, it is possible to find an area in which the spacing of the aperture rays that is determined in pairs becomes minimal. This area represents the entrance pupil or an area conjugate thereto in real space. For example, this area exhibits a finite curvature.

It may be the case that the projection optics unit 10 has different positions of the entrance pupil for the tangential beam path and for the sagittal beam path. In this case, an imaging element, for example an optical structural element, of the transfer optics unit, should be provided between the second facet mirror 22 and the reticle 7. Using this optical element, the different positions of the tangential entrance pupil and the sagittal entrance pupil may be taken into account.

In the arrangement of the components of the illumination optics unit 4 illustrated in FIG. 1, the second facet mirror 22 is arranged in an area conjugate to the entrance pupil of the projection optical unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged so as to be tilted with respect to an arrangement plane defined by the second facet mirror 22.

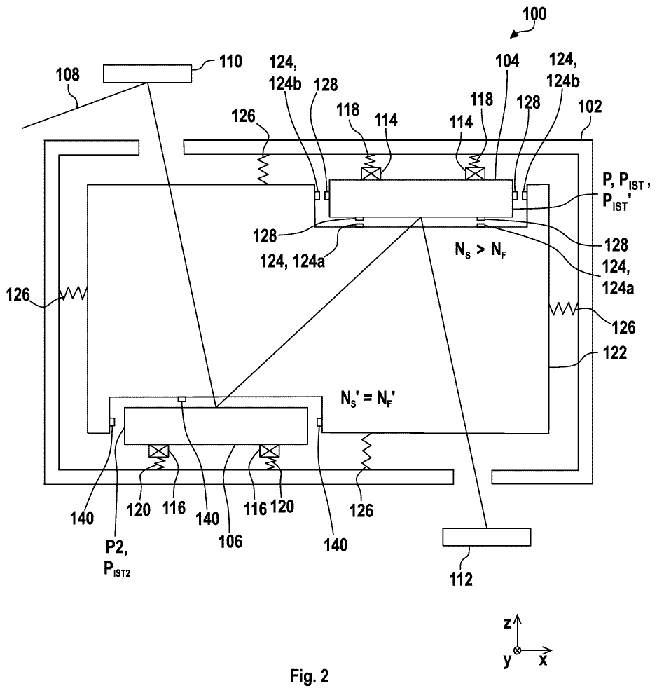

FIG. 2 shows an optical system 100 of the projection exposure apparatus 1 (lithography apparatus 1) from FIG. 1 according to one embodiment. For example, the optical system 100 is a projection optics unit 10 or part of a projection optics unit 10 of the lithography apparatus 1 from FIG. 1.

The optical system 100 comprises a force frame 102. For example, the force frame 102 is mounted in vibration-decoupled fashion on a floor (not shown here).

The optical system 100 also comprises one or more optical elements 104, 106. For example, the optical elements 104, 106 are mirrors M1 to M6 of the lithography apparatus 1, e.g. the projection optics unit 10, from FIG. 1. For example, operating light 108 (e.g. EUV light) of the lithography apparatus is steered to a mask 110 (reticle), similar to the mask 7 in FIG. 1. The optical system 100 is used to project an image of the mask 110 onto a substrate 112, for example a silicon wafer, which is coated with a light-sensitive layer (photoresist) and arranged in the image plane of the optical system 100. In this case, the operating light 108 is steered via the two mirrors 104, 106, shown by way of example in FIG. 2, or else via more than two mirrors of the optical system 100.

Hereinafter, the optical elements 104, 106 are described as mirrors 104, 106, with attention being drawn to the fact that there may also be optical elements other than mirrors in other examples.

Using actuators 114, 116, the mirrors 104, 106 are attached so as to be movable on the force frame 102. Even though only two actuators 114, 116 are visible in each case in FIG. 2, each mirror 104, 106 for example comprises at least three and/or six actuators 114, 116. Moreover, the mirrors 104, 106 are for example mounted in vibration-decoupled fashion (vibration decoupling devices 118, 120) on the force frame 102.

For example, a first mirror 104 of the mirrors 104, 106 comprises a plurality of actuators 114 that are coupled to the mirror 104 and serve to set a position P of the mirror 104 in a first number N_{F} of rigid body degrees of freedom.

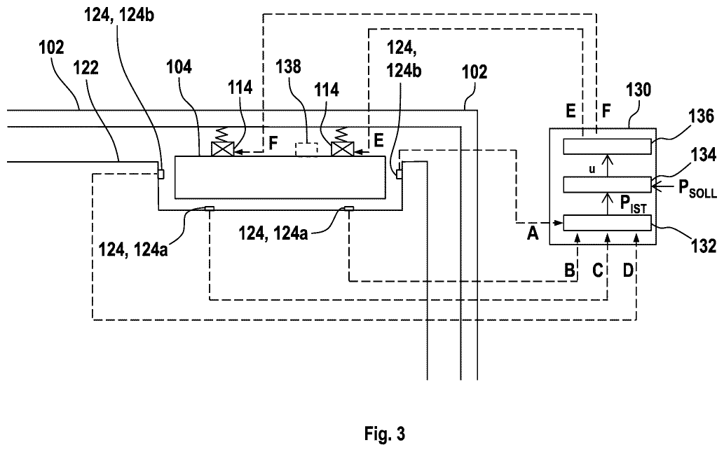

To detect an actual position P_{IST} of the mirror 104, the optical system 100 comprises a sensor frame 122 having a plurality of sensor elements 124 for acquiring sensor data A-D (FIG. 3) of the mirror 104. With the aid of the sensor elements 124, it is possible to measure the actual position P_{IST} of the mirror 104 relative to the sensor frame 122.

For example, the sensor frame 122 is mounted in vibration-decoupled fashion (vibration decoupling devices 126) with respect to the force frame 102.

For example, the sensor elements 124 are interferometers or other measuring apparatuses for detecting the actual position P_{IST} of the mirror 104. For example, each of the sensor elements 124 is configured to carry out a one-dimensional position measurement, e.g. a distance measurement. For example, the mirror 104 may comprise a plurality of target elements 128, for example reflector elements, in order to reflect a light (e.g. laser light) transmitted by the sensor elements 124.

For example, the mirror 104 is mounted with the aid of a plurality of actuators 114 in order to set the position P of the mirror 104 in six rigid body degrees of freedom (first number N_{F}=6). For example, the six rigid body degrees of freedom comprise a translation in the X-direction, in the Y-direction and in the Z-direction as well as a rotation about the X-axis, about the Y-axis and about the Z-axis.

Conventionally, detection of the actual position P_{IST} of the mirror 104 makes use of a number N_{S} of sensor elements 124 that corresponds to the number NF of rigid body degrees of freedom.

However, movable parts in the optical system 100 may cause mechanical disturbances and hence deformations of the sensor frame 122 which prevent an accurate position measurement of the mirror 104 relative to the sensor frame 122. For example, the disturbances of the sensor frame 122 may be quasi-static disturbances or dynamic disturbances (vibrational excitations). For example, the sensor frame 122 may deform (periodically or non-periodically) as a result of a mechanical disturbance. This leads to an error in the ascertained actual position P_{IST} of the mirror 104, which as a consequence leads to an imaging error of the optical system 100.

It is desirable to detect a deformation of the sensor frame 122 and take this into account when ascertaining the actual position P_{IST} of the mirror 104. To this end, the “over-sensing” principle is used. For example, the optical system 100 according to FIG. 2 comprises more sensor elements 124 for ascertaining the actual position P_{IST} of the mirror 104 than are needed for a determination of the rigid body position of the mirror 104. For example, the number N_{S} of sensor elements 124 that are arranged on the sensor frame 122 and serve to measure the mirror 104 is greater than the number N_{F} of rigid body degrees of freedom of the mirror 104.

For example, the number N_{S} of sensor elements 124 that are arranged on the sensor frame 122 and serve to measure the mirror 104 is seven or more. FIG. 2 only shows four of e.g. seven sensor elements 124. For example, the sensor frame 122 comprises four vertical sensor elements 124a for detecting a vertical movement (Z-direction in FIG. 2), two of which are visible in FIG. 2. Furthermore, the sensor frame 122 for example comprises three horizontal sensor elements 124b for detecting a horizontal movement (in the XY-plane in FIG. 2), two of which are visible in FIG. 2.

The optical element 104 may comprise a target element 128 (e.g. reflector element) assigned to each sensor element 124 and thus comprise seven or more target elements 128.

Thus, an additional sensor element 124 is provided for detecting a deformation of the mirror 104 in the case of seven sensor elements 124 (N_{S}=7) and six rigid body degrees of freedom of the mirror 104 (N_{F}=6). Accordingly, more than one additional sensor element 124 is present for detecting a deformation of the mirror 104 in the case of more than seven sensor elements 124 (N_{S}>7) and six rigid body degrees of freedom of the mirror 104 (N_{F}=6).

FIG. 3 shows an enlarged partial detail from FIG. 2. As shown in FIG. 3, the optical system 100 comprises a control apparatus 130. The control apparatus 130 comprises an ascertainment device 132, which receives sensor data A, B, C, D from the sensor elements 124. The ascertainment device 132 is configured to ascertain (e.g. calculate) a deformation-corrected actual position P_{IST} of the mirror 104 on the basis of the sensor data A, B, C, D. The deformation-corrected actual position P_{IST} of the mirror 104 is a rigid body position of the mirror 104, in which a deformation of the sensor frame 122 was taken into account, i.e. corrected.

The control apparatus 130 moreover comprises a closed-loop control device 134 for controlling the position P of the mirror 104. The closed-loop control device 134 receives the deformation-corrected actual position P_{IST} of the mirror 104, as ascertained by the ascertainment device 132. The closed-loop control device 134 is configured to calculate a deviation between the deformation-corrected actual position P_{IST} of the mirror 104 and a target position P_{SOLL} of the mirror 104. On the basis of the calculated deviation, the closed-loop control device 134 ascertains a manipulated variable u, which is transmitted to a controlling device 136. The controlling device 136 transmits a control signal E, F to each actuator 114, in order to move the mirror 104 into the target position P_{SOLL}. Since a possible deformation of the sensor frame 122 has already been corrected when determining the deformation-corrected actual position P_{IST} of the mirror 104, a deformation of the sensor frame 122 does not lead to a faulty control of the mirror position.

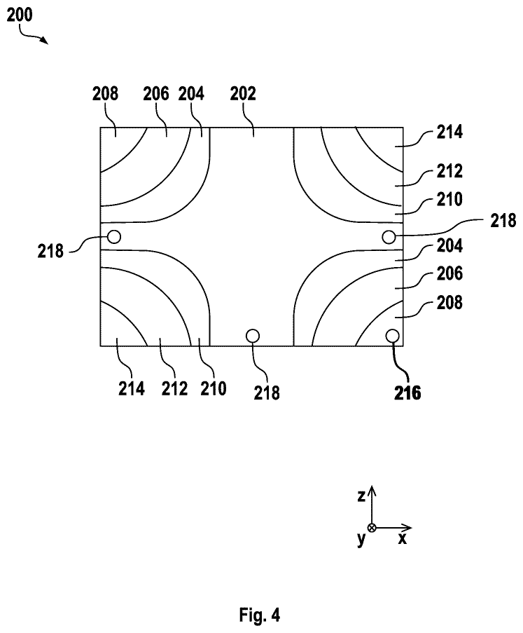

As illustrated purely in general terms and schematically in FIG. 4, sensor elements 216, 218 may be placed on a sensor frame 200 (like the sensor elements 124 are placed on the sensor frame 122 in FIG. 2) in accordance with an expected deflection of individual regions of the sensor frame 200 on account of disturbances. FIG. 4 shows a sensor frame 200 according to a further embodiment. Moreover, FIG. 4 shows a snapshot of a torsional mode of the sensor frame 200, in which a central region 202 does not experience any deflection and is therefore referred to as non-deflection region 202. The non-deflection region 202 of the sensor frame 202 does not move during a deformation in accordance with the illustrated torsional mode. In the case of a dynamic vibrational excitation of the sensor frame 200, a non-deflection region may also be referred to as a nodal region of an eigenmode of the sensor frame 200.

Moreover, the regions 204, 206 and 208 are regions of the sensor frame 200 with deflections in the positive Y-direction (into the plane of the drawing in FIG. 4), with a magnitude of the deflection (e.g. an amplitude) increasing from region 204 to region 208. That is to say the regions 208 are regions of maximal deflection. Additionally, the regions 210, 212 and 214 are regions of the sensor frame 200 with deflections in the negative Y-direction (out of the plane of the drawing in FIG. 4), with a magnitude of the deflection (e.g. an amplitude) increasing from region 210 to region 214. That is to say the regions 214 are also regions of maximal deflection.

Reference sign 216 denotes a sensor element that is arranged on the sensor frame 200 in a region 208 of a deflection, for example a maximal deflection, of the sensor frame 200 in relation to a quasi-static and/or a dynamic disturbance (in relation to the shown torsional mode in the example of FIG. 4).

FIG. 4 shows a dynamic disturbance (i.e. a vibrational excitation) of the sensor frame 200 in an eigenmode with a corresponding eigenfrequency. In this case, it might be the that the sensor element 216 is arranged in a region 208 of a maximal vibration amplitude of the sensor frame 200 in relation to the eigenmode of the sensor frame 200.

By arranging one or more sensor elements 218 that are not required for ascertaining the rigid body position (additional sensor elements) in a region of an (e.g. maximal) deflection of the sensor frame in relation to a quasi-static and/or a dynamic disturbance, it is possible to detect a deformation of the sensor frame 200 on account of the corresponding disturbance particularly well.

Reference sign 218 denotes sensor elements that are arranged on the sensor frame 200 in the non-deflection region 202 in relation to a quasi-static and/or a dynamic disturbance.

By arranging the sensor elements 218 in the non-deflection region 202, the sensor elements 218 will not detect the eigenmode illustrated in FIG. 4 and may be used particularly well for the detection of the position of the mirror 104 as a rigid body.

In the optical system 100 in FIG. 2, six of the e.g. seven sensor elements 124 (FIG. 2) may be arranged in a corresponding non-deflection region of the sensor frame 122 (similar to the non-deflection region 202 of the sensor frame 200 in FIG. 4) in relation to a quasi-static and/or a dynamic disturbance. Furthermore, the additional seventh sensor element 124 may be arranged in a region of a deflection, e.g. a maximum deflection (similar to the regions 208, 214 in FIG. 4), in relation to the quasi-static and/or dynamic disturbance. As shown using dashed lines in FIG. 3, the optical system 100 may optionally comprise a vibration sensor device 138. The vibration sensor device 138 serves to capture one or more excitation frequencies G of a vibrational excitation of the optical system 100, e.g. of the mirror 104. The vibration sensor device 138 comprises e.g. one or more vibration sensors, for example one or more piezo elements or the like. Even though FIG. 3 shows that the vibration sensor device 138 is attached to the mirror 104, the vibration sensor device 138 or one or more vibration sensors of the vibration sensor device 138 may also be attached at different locations and/or to different components of the optical system 100.

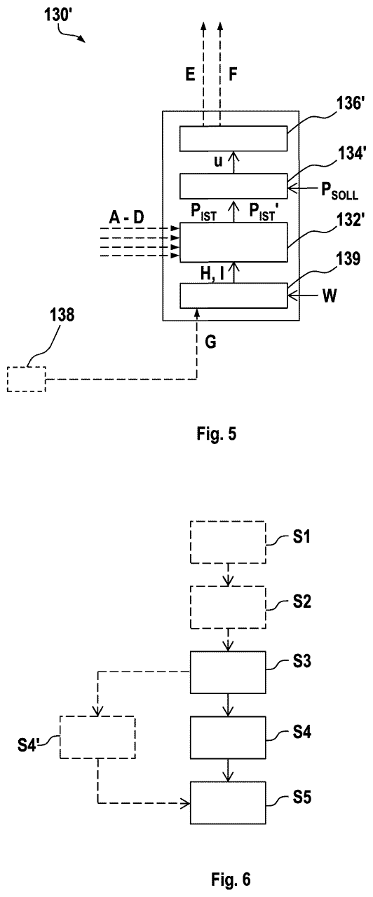

Furthermore, the optical system 100 may comprise an evaluation device 139 (FIG. 5), which receives the value G (or the values G) of the excitation frequency, as detected by the vibration sensor device 138. For example, the evaluation device 139 is part of the control apparatus 130′, as shown in FIG. 5. The evaluation device 139 is configured to compare the received value or values G of the excitation frequency with a predetermined threshold value W. For example, the predetermined threshold value W is 500 Hz or 200 Hz. The threshold value W may also take other values in other examples, e.g. 1 kHz, 750 Hz, 300 Hz, 100 Hz, 50 Hz, 20 Hz or 10 Hz. Detection of the excitation frequencies G of the optical system 100 serves to ascertain whether the mirror 104 behaves at least approximately as a rigid body. For example, the threshold value W is ascertained or selected in such a way that the mirror 104 may be assumed to be a rigid body at excitation frequencies below the threshold value W.

Should the evaluation device 139 ascertain that the one or more excitation frequencies G detected by the vibration sensor device 138 are less than or equal to the predetermined threshold value W, then it transmits a control signal H to the ascertainment device 132′ to ascertain the deformation-corrected actual position P_{IST} of the mirror 104, in the case of which the deformation of the sensor frame 122 is corrected. This is because the mirror 104 may be assumed to be a rigid body in this case, and so the sensor data A to D may be used to correct a deformation of the sensor frame 122.

Should the evaluation device 139 ascertain that the one or more excitation frequencies G detected by the vibration sensor device 138 are greater than the predetermined threshold value W, then a case is present in which the mirror 104 cannot be assumed to be rigid. However, the sensor frame 122 may be assumed to be rigid. In this case, the evaluation device 139 transmits a control signal I to the ascertainment device 132′ to correct a deformation of the mirror 104—rather than a deformation of the sensor frame 122. In other words, the ascertainment device 132′ will ascertain a further actual position P_{IST}′ of the mirror 104, in which a deformation of the mirror 104 is corrected, should the one or more excitation frequencies G be greater than the predetermined threshold value W.

As shown in FIG. 2, the optical system 100 may comprise further mirrors 106 in addition to the mirror 104. By way of example, a further mirror 106 is shown in FIG. 2, and is mounted so as to be movable on the force frame 102 via actuators 116. Although this is not shown in FIG. 2, the optical system 100 may also comprise more than one further mirror 106.

The further mirror 106 has a third number N_{F}′ of rigid body degrees of freedom, e.g. six as well. Furthermore, the sensor frame 122 comprises a plurality of sensor elements 140 for the further mirror 106, similar to the sensor elements 124 for the first mirror 104. The sensor elements 140 serve to acquire sensor data from the mirror 106 in order to measure a position P_{IST2} of the mirror 106. For example, the sensor frame 122 comprises just as many sensor elements 140 (total: N_{S}′) for the further mirror 106 as the further mirror 106 has rigid body degrees of freedom. Since a deformation of the sensor frame 122 has already been detected with the aid of the sensor elements 124 for the first mirror 104 by using the principle of “over-sensing” (N_{S}>N_{F}), the deformation of the sensor frame 122 need not be detected again for the further mirror 106.

Consequently, the ascertainment device 132 may be configured to use the sensor data A, B, C, D from the first optical element 104 to ascertain a deformation of the sensor frame 122. Moreover, the ascertainment device 132 may be configured to use the sensor data from the further mirror 106, acquired via the sensor elements 140, to ascertain a deformation-corrected actual position P_{IST2} of the further mirror 106 relative to the sensor frame 122 on the basis of the deformation of the sensor frame 122 ascertained for the first optical element 104. In that case, the position P2 of the further mirror 106 may be controlled on the basis of the deformation-corrected actual position P_{IST2} of the further mirror 106 ascertained in this way.

A method for operating an optical system 100 of a lithography apparatus 1 is described below with reference to FIG. 6. The optical system 100 (FIG. 2) comprises an optical element 104, for example a mirror, and a plurality of actuators 114 that are coupled to the optical element 104 and serve to set a position P of the optical element 104 in a first number N_{F} of rigid body degrees of freedom.

In a first optional step S1 of the method, one or more excitation frequencies G of a vibrational excitation of the optical system 100 are captured.

In a second optional step S2 of the method, there is an ascertainment as to whether the one or more excitation frequencies G detected in S1 are less than or equal to a predetermined threshold value W.

In a third step S3 of the method, sensor data A-D from the optical element 104 are acquired with the aid of a second number N_{S} of sensor elements 124 on a sensor frame 122, wherein the second number N_{S} is greater than the first number N_{F}.

In a fourth step S4 of the method, the sensor data A-D acquired in S3 are used to ascertain a deformation-corrected actual position P_{IST} of the optical element 104 relative to the sensor frame 122 in the first number N_{F} of rigid body degrees of freedom, wherein a deformation of the sensor frame 122 is corrected in the deformation-corrected actual position P_{IST}.

If optional steps S1 and S2 were performed previously, then step S4 can be carried out on the basis of the result of step S2. For example, step S4 might only be carried out if the one or more detected excitation frequencies G were ascertained to be less than or equal to the predetermined threshold value W in step S2.

By contrast, should the one or more detected excitation frequencies G be ascertained as being greater than the predetermined threshold value W in step S2, then an optional step S4′ may be carried out instead of step S4.

Should the detected excitation frequencies G be greater than the predetermined threshold value W, a further actual position P_{IST}′ of the optical element 104, in which a deformation of the optical element 104—rather than a deformation of the sensor frame 122 as in S4 is corrected, is ascertained in the first number N_{F} of rigid body degrees of freedom on the basis of the sensor data A-D in an optional step S4′ of the method.

In a fifth step S5 of the method, the position P of the optical element 104 is controlled, for example in a feedback control loop. In this case, the position P of the optical element 104 is controlled on the basis of a deviation of the ascertained deformation-corrected actual position P_{IST}, in which a deformation of the sensor frame 122 is corrected, from a target position or—should step S4′ have been performed previously—on the basis of a deviation of the ascertained further actual position P_{IST}′, in which a deformation of the optical element 104 is corrected, from a target position.

Using the proposed optical system 100 (FIG. 2) and the proposed method (FIG. 6), it is consequently possible to detect and correct a deformation of the sensor frame 122, relative to which the position P_{IST} of the optical element 104 is measured, by exploiting the “over-sensing” principle. As a result, it is possible to achieve higher imaging accuracies of the optical system 100 and hence of the lithography apparatus 1. Optionally, it is possible to take account of the frequency ranges of excitation frequencies G in which the optical element 104 or the sensor frame 122 may be meaningfully considered to be a rigid body.

Although the present disclosure has been described on the basis of exemplary embodiments, it is modifiable in diverse ways.

### LIST OF REFERENCE SIGNS

1 Projection exposure apparatus
2 Illumination system
3 Light source
4 Illumination optics unit
5 Object field
6 Object plane
7 Reticle
8 Reticle holder
9 Reticle displacement drive
10 Projection optics unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Optical system
102 Force frame
104 Optical element
106 Optical element
108 Operating light
110 Mask
112 Substrate
114 Actuator
116 Actuator
118 Vibration decoupling device
120 Vibration decoupling device
122 Sensor frame
124 Sensor element
124a, 124b Sensor element
126 Vibration decoupling device
128 Target element
130 Control apparatus
132, 132′ Ascertainment device
134, 134′ Closed-loop control device
136 Controlling device
138 Vibration sensor device
140 Sensor element
A-D Sensor data
E, F Control signal
G Value
H, I Control signal
M1-M6 Mirrors
N_{F}, N_{F}′ Number
N_{S}, N_{S}′ Number
P, P′, P2 Position
P_{IST} Actual position
P_{IST}', P_{IST2} Actual position
P_{SOLL} Target position
S1-S5, S4′ Method steps
u Manipulated variable
W Threshold value
X, Y, Z Directions

What is claimed is:

1. An optical system, comprising:
an optical element;
a plurality of actuators coupled to the optical element to set a position of the optical element in a first number of rigid body degrees of freedom;
a sensor frame comprising a second number of sensor elements configured to acquire sensor data from the optical element, the second number greater than the first number; and
an ascertainment device configured to ascertain, based on the sensor data, a deformation-corrected actual position of the optical element relative to the sensor frame in the first number of rigid body degrees of freedom,
wherein a deformation of the sensor frame is corrected in the deformation-corrected actual position.

2. The optical system of claim 1, wherein the ascertainment device is configured to correct, based on the sensor data, a quasi-static deformation of the sensor frame.

3. The optical system of claim 1, wherein the ascertainment device is configured to correct, based on the sensor data, a dynamic deformation of the sensor frame.

4. The optical system of claim 1, wherein at least one of the sensor elements is in a region of a deflection of the sensor frame relative in relation to a quasi-static disturbance and/or a dynamic disturbance.

5. The optical system of claim 1, wherein each of a number of sensor elements, the number corresponding to the first number, is in a non-deflection region of the sensor frame in relation to a quasi-static and/or a dynamic disturbance.

6. The optical system of claim 1, further comprising a vibration sensor device configured to detect one or more excitation frequencies of a vibrational excitation of the optical system,
wherein the ascertainment device is configured to ascertain the deformation-corrected actual position of the optical element, in the case of which a deformation of the sensor frame is corrected, when the one or more detected excitation frequencies are less than or equal to a predetermined threshold value.

7. The optical system of claim 6, wherein the ascertainment device is configured to ascertain, based on the sensor data, a further actual position of the optical element in the first number of rigid body degrees of freedom when the one or more detected excitation frequencies are greater than the predetermined threshold value, wherein a deformation of the optical element is corrected at the further actual position.

8. The optical system of claim 6, wherein the predetermined threshold value is selected from the group consisting of 1 kiloHertz (kHz), 750 Hz, 500 Hz, 300 Hz, 200 Hz, 100 Hz, 50 Hz, 20 Hz, and 10 Hz.

9. The optical system of claim 1, further comprising a closed-loop control device configured to control the position of the optical element based on: i) a deviation of the deformation-corrected actual position, in which a deformation of the sensor frame is corrected, from a target position; or ii) a deviation of the ascertained further actual position, in which a deformation of the optical element is corrected, from a target position.

10. The optical system of claim 1, wherein the optical element is a first optical element, and the optical system further comprises:
a second optical element; and
a plurality of actuators coupled to the second optical element to set a position of the second optical element in a third number of rigid body degrees of freedom, wherein:
the sensor frame comprises a number of sensor elements, the number corresponding to the third number, to acquire sensor data from the second optical element; and
the ascertainment device is configured to:
i) based on the sensor data from the first optical element, ascertain a deformation of the sensor frame; and
ii) based on the sensor data from the second optical element, ascertain a deformation-corrected actual position of the second optical element relative to the sensor frame in the third number of rigid body degrees of freedom based on the deformation of the sensor frame ascertained for the first optical element.

11. The optical system of claim 1, wherein:
the ascertainment device is configured to correct, based on the sensor data, a quasi-static deformation of the sensor frame; and
the ascertainment device is configured to correct, based on the sensor data, a dynamic deformation of the sensor frame.

12. The optical system of claim 1, wherein:
the ascertainment device is configured to correct, based on the sensor data, a quasi-static deformation of the sensor frame; and
at least one of the sensor elements is in a region of a deflection of the sensor frame relative in relation to a quasi-static disturbance and/or a dynamic disturbance.

13. The optical system of claim 1, wherein:
the ascertainment device is configured to correct, based on the sensor data, a quasi-static deformation of the sensor frame; and
each of a number of sensor elements, the number corresponding to the first number, is in a non-deflection region of the sensor frame in relation to a quasi-static and/or a dynamic disturbance.

14. The optical system of claim 1, wherein:
the ascertainment device is configured to correct, based on the sensor data, a quasi-static deformation of the sensor frame;
the optical system further comprises a vibration sensor device configured to detect one or more excitation frequencies of a vibrational excitation of the optical system; and
wherein the ascertainment device is configured to ascertain the deformation-corrected actual position of the optical element, in the case of which a deformation of the sensor frame is corrected, when the one or more detected excitation frequencies are less than or equal to a predetermined threshold value.

15. The optical system of claim 1, wherein:
the ascertainment device is configured to correct, based on the sensor data, a quasi-static deformation of the sensor frame;
the ascertainment device is configured to correct, based on the sensor data, a dynamic deformation of the sensor frame; and
at least one of the sensor elements is in a region of a deflection of the sensor frame relative in relation to a quasi-static disturbance and/or a dynamic disturbance.

16. An apparatus, comprising:
an optical system according to claim 1,
wherein the apparatus is a lithography apparatus.

17. A method for operating an optical system of a lithography apparatus, the optical system comprising an optical element and a plurality of actuators coupled to the optical element to set a position of the optical element in a first number of rigid body degrees of freedom, the method comprising:
a) acquiring sensor data from the optical element with the aid of a second number of sensor elements on a sensor frame, the second number greater than the first number; and
b) using the sensor data to ascertain a deformation-corrected actual position of the optical element relative to the sensor frame in the first number of rigid body degrees of freedom,
wherein a deformation of the sensor frame is corrected in the deformation-corrected actual position.

18. The method of claim 17, further comprising detecting one or more excitation frequencies of a vibrational excitation of the optical system, wherein b) is performed when the one or more detected excitation frequencies are less than or equal to a predetermined threshold value.

19. The method of claim 18, further comprising, when the one or more detected excitation frequencies is greater than the predetermined threshold value, ascertaining a further actual position of the optical element, in which a deformation of the optical element is corrected, in the first number of rigid body degrees of freedom based on the sensor data.

20. The method of claim 17, further comprising controlling the position of the optical element based on: i) a deviation of the deformation-corrected actual position, in which a deformation of the sensor frame is corrected, from a target position; or ii) a deviation of the further actual position, in which a deformation of the optical element is corrected, from a target position.
